(19) United States
(12) Patent Application Publication
(10) Pub. No.: US 2008/0282122 A1
(43) Pub. Date: Nov. 13, 2008

(54) SINGLE SCAN CLOCK IN A MULTI-CLOCK DOMAIN

(76) Inventor: Amar Guettaf, Sunnyvale, CA (US)

Correspondence Address: MCANDREWS HELD & MALLOY, LTD, 500 WEST MADISON STREET, SUITE 3400, CHICAGO, IL, 60661, US

(21) Appl. No.: 11/746,450

(22) Filed: May 9, 2007

(51) Int. Cl. G01R 31/3177

(52) U.S. Cl. 714/731

(57) ABSTRACT

Herein described are at least a method and a system to perform scan testing of an integrated circuit chip. The integrated circuit chip is scan tested using only a single scan clock. The single scan clock is provided through a single pin on the integrated circuit chip. In a representative embodiment, the method comprises inputting a single scan clock, first shifting data into one or more flip-flops of one or more scan chains by clocking the data into one or more scan in (SI) inputs of the one or more flip-flops using the single scan clock, selectively clocking flip-flops of a clock domain, and second shifting data from said one or more flip-flops of said one or more scan chains. In a representative embodiment, the system comprises one or more clock domains and one or more clock domain scan test modules.

### CROSS-REFERENCE TO RELATED APPLICATIONS/INCORPORATION BY REFERENCE

[Not Applicable]

### FEDERALLY SPONSORED RESEARCH OR DEVELOPMENT

[Not Applicable]

### MICROFICHE/COPYRIGHT REFERENCE

[Not Applicable]

### BACKGROUND OF THE INVENTION

When testing digital integrated circuit chips, it is important to be able to identify independent clock domains and to test each of these independent clock domains using a scan clock. Typically, a scan clock is provided to a clock domain using a pin or pad of an integrated circuit chip. If there are a number of clock domains, the number of pins or pads may be significantly large, resulting in a difficult implementation. Furthermore, an integrated circuit chip that uses a large number of scan clocks may result in cross clock domain capture violations and high power consumption.

The limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Various aspects of the invention provide a method and a system of scan testing an integrated circuit chip by way of using only a single scan clock. The various aspects and representative embodiments of the method and system are substantially shown in and/or described in connection with at least one of the following figures, as set forth more completely in the claims.

These and other advantages, aspects, and novel features of the present invention, as well as details of illustrated embodiments, thereof, will be more fully understood from the following description and drawings.

### BRIEF DESCRIPTION OF THE DRAWINGS

FIG. 1 is a block diagram representation of a plurality of scan clock input pins and corresponding clock domains of a typical integrated circuit chip.

FIG. 2 is a relational block diagram of one or more functional components within an integrated circuit chip that utilize a single scan clock to perform scan testing, in accordance with an embodiment of the invention.

FIG. 3A is a detailed block diagram of a clock domain scan test module (CDSTM) of the one or more clock domain scan test modules in a digital integrated circuit chip, as previously described in connection with FIG. 2, in accordance with an embodiment of the invention.

FIG. 3B is a block diagram of a clock domain that is clocked by its corresponding clock domain scan test module (CDSTM), in accordance with an embodiment of the invention.

FIG. 4 is an operational flow diagram describing scan testing of an integrated circuit chip by way of using a single scan clock, in accordance with an embodiment of the invention.

### DETAILED DESCRIPTION OF THE INVENTION

Various aspects of the invention can be found in a method and a system to perform scan testing of an integrated circuit chip. The integrated circuit chip may comprise a digital integrated circuit chip comprising a plurality of scan chains. Each scan chain may comprise a plurality of flip-flops. In accordance with the various aspects of the invention, the scan testing may be performed using a single scan clock, as opposed to a plurality of scan clocks. The single scan clock is supplied to the integrated circuit chip by way of using a single pin on the integrated circuit chip. Various aspects of the invention provide control of the single scan clock to allow selective testing of one or more clock domains (i.e., digital circuitry or gates which utilize the same clock signal). The circuitry that is tested may comprise one or more flip-flops associated with a particular clock domain, for example. The one or more flip-flops may originate from one or more scan chains in the integrated circuit chip. Advantages of using a single scan clock include lower pin count and reduced integrated circuit size. As a consequence of employing the method and system of the present invention, a lower maximum power consumption may be attained as one or more certain clock domain(s) are selectively tested. Further, use of a single scan clock as opposed to multiple scan clocks alleviate the occurrence of cross clock domain capture violations and cross clock interference.

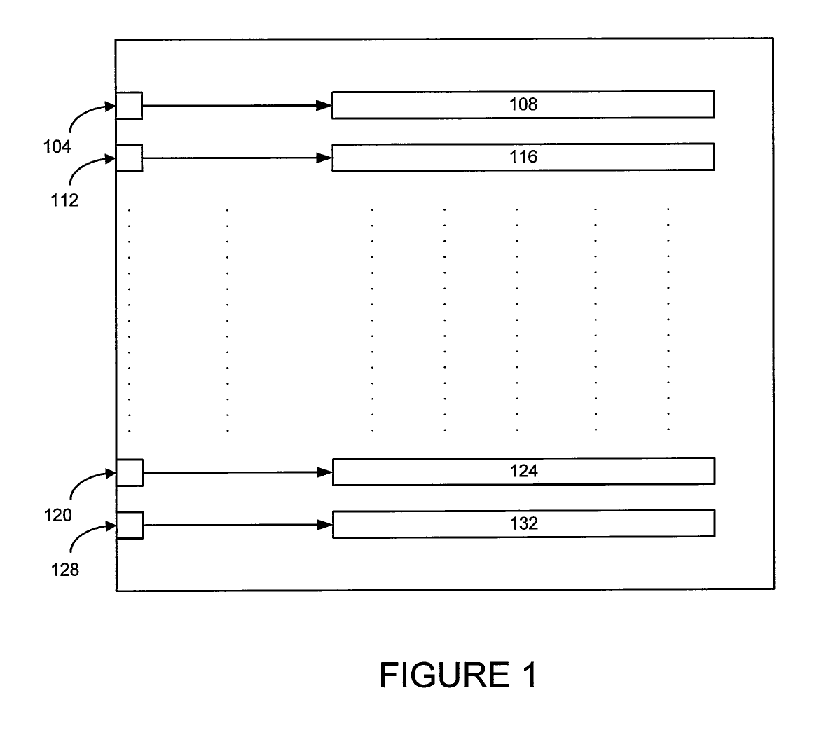

FIG. 1 is a block diagram representation of a plurality of scan clock input pins 104, 112, 120, 128 and corresponding clock domains 108, 116, 124, 132 of a typical integrated circuit chip. The scan clock input pins 104, 112, 120, 128 and corresponding clock domains 108, 116, 124, 132 may be used in scan testing the typical integrated circuit chip. Each of the scan clock input pins 104, 112, 120, 128 may be used to provide a connection in which an external scan clock may be input into the integrated circuit chip. The scan clock may be used to perform scan testing of one or more flip-flops of a clock domain. As illustrated, a first scan clock may be provided to the chip through the use of the first scan clock input pin 104, a second scan clock may be provided to the chip through the use of the second scan clock input pin 112, and so forth and so on, until a (n−1)th scan clock may be provided to the chip through the use of the (n−1)th scan clock input pin 120, and a nth scan clock may be provided to the chip through the use of the nth scan clock input pin 128. The first scan clock provides a clock signal for the first clock domain 108, the second scan clock provides a clock signal for the second clock domain 116, the (n−1)th scan clock provides a clock signal for the (n−1)th clock domain 124, while the nth scan clock provides a clock signal for the nth clock domain 132. The one or more flip-flops of each clock domain may originate from any of one or more scan chains. Typically, the integrated circuit chip may be designed such that a scan clock is transmitted to the clock inputs of all flip-flops associated with a corresponding clock domain.

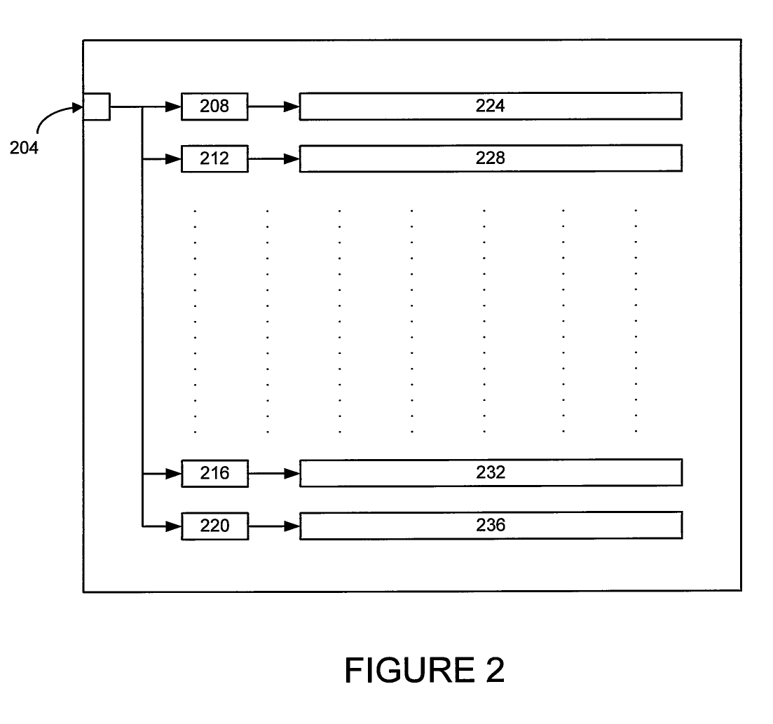

FIG. 2 is a relational block diagram of one or more functional components within an integrated circuit chip that utilize a single scan clock to perform scan testing, in accordance with an embodiment of the invention. The one or more functional components may be used to selectively clock one or more clock domains, in accordance with an embodiment of the invention. The integrated circuit chip comprises a pin 204 that is used to input a scan clock. An external source may provide the scan clock; the external source may comprise an automatic test equipment (ATE). The scan clock may be distributed from the pin 204 to a first clock domain scan test module (CDSTM) 208, a second CDSTM 212, . . . , a (n−1)th CDSTM 216, and a nth CDSTM 220. Each of these one or more clock domain scan test modules (CDSTMs) 208, 212, 216, 220 generates a clock signal to its corresponding clock domain 224, 228, 232, 236. As illustrated, the first CDSTM 208 outputs a first clock signal to the first clock domain 224, the second CDSTM 212 outputs a second clock signal to the second clock domain 228, . . . , the (n−1)th CDSTM 216 outputs a (n−1)th clock signal to the (n−1)th clock domain 232, and a nth CDSTM 220 outputs the nth clock signal to the nth clock domain 236. Each of the clock domains 224, 228, 232, 236 may comprise one or more flip-flops originating from one or more scan chains. The one or more flip-flops of a clock domain may not necessarily originate from a single scan chain. In a representative embodiment, the one or more CDSTMs 208, 212, 216, 220 may be used to selectively clock a single clock domain of the one or more clock domains 224, 228, 232, 236 during a capture mode. Selective clocking is performed by way of connecting the output of a CDSTM to the input of its corresponding clock domain. For example, the output of the CDSTM may be connected to the clock input of a first flip-flop in a clock domain. A capture mode may occur, for example, when the data (D) inputs of flip-flops of one or more clock domains or scan chains are clocked. On the other hand, a shift mode occurs, for example, when the shift in (SI) inputs of flip-flops of one or more clock domains or scan chains are clocked. This occurs by way of control provided through the scan enable (SE) (or test enable (TE)) input of the flip-flop. The flip-flop may originate from any of the one or more clock domains or one or more scan chains within the integrated circuit chip. In another representative embodiment, the one or more CDSTMs 208, 212, 216, 220 may be used to selectively clock a subset of the one or more clock domains 224, 228, 232, 236. By clocking only one or a subset of the one or more clock domains 224, 228, 232, 236, cross clock domain violations may be minimized and power consumption may be suitably controlled. For example, maximum power consumption may be controlled in the integrated circuit chip by selectively clocking a subset of the one or more clock domains 224, 228, 232, 236.

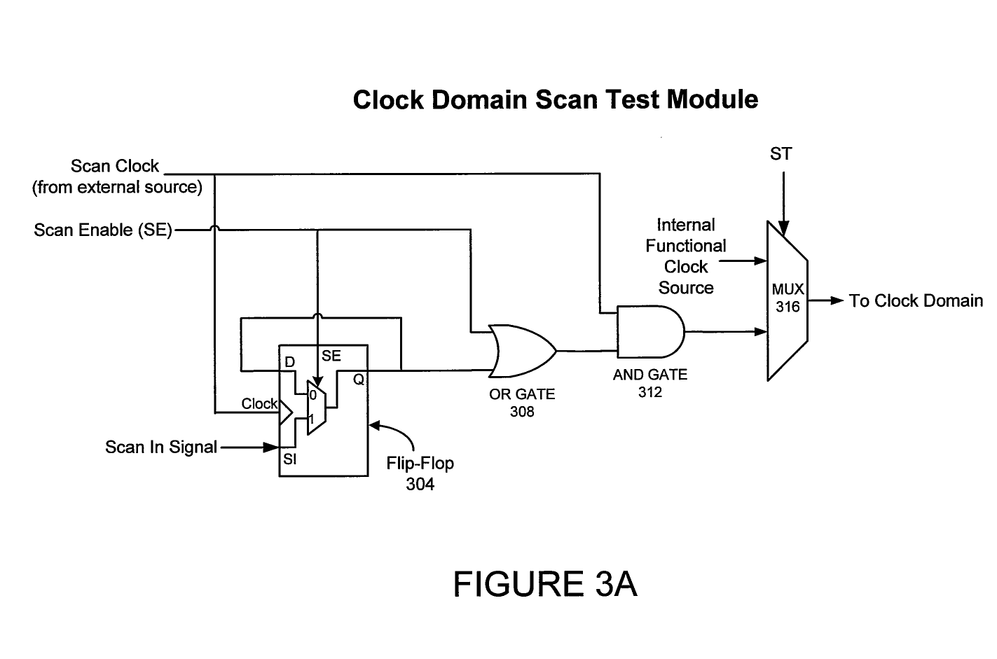

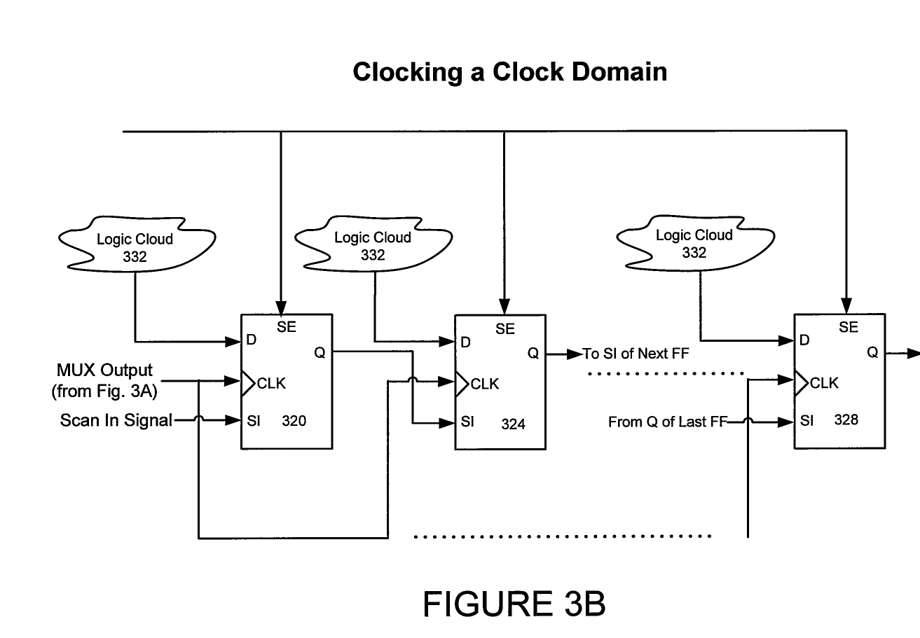

FIG. 3A is a detailed block diagram of a clock domain scan test module (CDSTM) of the one or more clock domain scan test modules in a digital integrated circuit chip, as previously described in connection with FIG. 2, in accordance with an embodiment of the invention. As described in connection with FIG. 2, the output of the CDSTM supplies a clock signal to its corresponding clock domain. The clock domain scan test module comprises a flip-flop 304, an OR gate 308, an AND gate 312, and a two input multiplexer 316. The flip-flop 304 is clocked by a single scan clock provided by an external source, such as an automatic test equipment (ATE). The single scan clock may be received by the integrated circuit chip by way of a single pin. The flip-flop 304 is configured such that its data (D) input is connected to its output (Q). The Q of the flip-flop 304 is fed back to the D input of the flip-flop 304. The flip-flop 304 is controlled by a first control signal referred to as a scan enable (SE) or test enable (TE) signal. In the representative embodiment illustrated in FIG. 3A, the first control signal is used to select a data (D) input or a scan in (SI) input of the flip-flop 304. The OR gate 308 receives the flip-flop output (Q) and the first control signal. The OR gate 308 transmits its output to the AND gate 312. The AND gate 312 receives the OR gate output and the single scan clock. The AND gate 312 transmits its output to the two input multiplexer 316. The two input multiplexer 316 receives an internal functional clock of the digital integrated circuit chip and the output of the AND gate as inputs. Either the internal functional clock or the output of the AND gate may be selected by the two input multiplexer 316 by using a control signal referred to as a scan test (ST) signal. The ST signal may be used to control whether scan test mode is enabled or disabled. When scan test is disabled, an internal functional clock source is used as a clock source by an associated clock domain. When ST is enabled, the scan clock is used as a clock source by the associated clock domain. The AND gate 312 transmits the output of the clock domain scan test module (CDSTM) to a corresponding clock domain. The clock domain may comprise a string of flip-flops configured as a scan chain. The scan enable (SE) signal may be used to clock data into the flip-flop using the SI input or using the D input of the flip-flop. Although not shown, the SE signal may be distributed as an input to one or more flip-flops of one or more scan chains (or the one or more clock domains) of the digital integrated circuit chip. The single scan clock and signal inputs to SE and SI may be provided by external sources that utilize one or more pins of said digital integrated circuit chip. The external source may comprise an automatic test equipment (ATE).

FIG. 3B is a block diagram of a clock domain that is clocked by its corresponding clock domain scan test module CDSTM), in accordance with an embodiment of the invention. The CDSTM described in connection with FIGS. 2 and 3A may be used to provide a clock to the clock domain. The clock domain comprises a total of n flip-flops. For the sake of simplicity, FIG. 3B illustrates a string of n flip-flops that are represented by a first flip-flop 320, a second flip-flop 324, and an nth flip-flop 328. The CDSTM supplies the clock to each of the clock inputs of the n flip-flops. The output (Q) of each flip-flop is connected to the scan in (SI) of the next flip-flop. Data may be clocked into the flip-flops using the SI inputs of each flip-flop during a “shift in”, “scan in”, or “scan out” mode. Data may also be clocked into the flip-flops using the D inputs of each flip-flop during a “capture” mode. The data that is clocked into the D inputs may comprise signals that have been processed by a logic cloud 332 of the clock domain. As shown, the clock domain comprises the logic cloud 332 and the n flip-flops 320, 324, 328. The logic cloud 332 may comprise various logic circuitry such as a plurality of logic gates. A digital integrated circuit may be designed with one or more clock domains configured in the same fashion as the clock domain pictured in FIG. 3B. Each of the clock domains may be clocked by its corresponding clock domain scan test module (CDSTM).

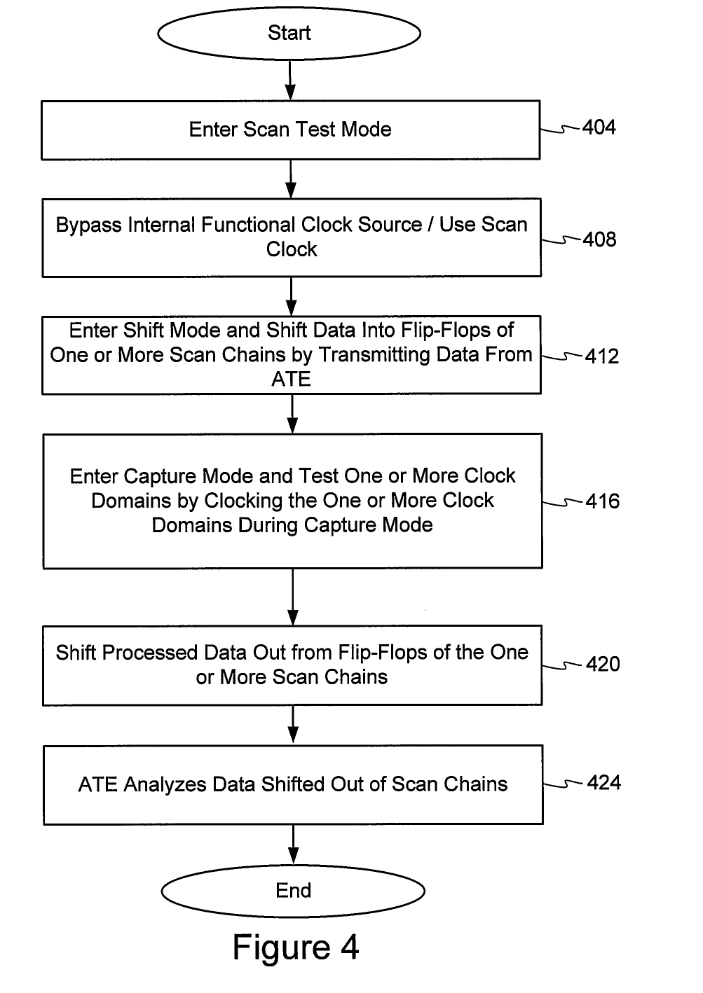

FIG. 4 is an operational flow diagram describing scan testing of an integrated circuit chip by way of using a single scan clock, in accordance with an embodiment of the invention. The single scan clock may be provided externally from the chip by an automatic test equipment (ATE). The single scan clock may be delivered to the chip by way of a conductive pin on the integrated circuit chip. At step 404, a user, for example, initiates scan testing of the integrated circuit chip. Next, at step 408, one or more internal functional clock sources are bypassed such that the single scan clock may be used during the scan testing process. The single scan clock is distributed to the one or more clock domain scan test modules (CDSTMs) throughout the integrated circuit chip. A control signal, such as the scan test (ST) signal previously mentioned in connection with FIG. 3A, may be used to switch between the internal functional clock and the scan clock. The ST signal selects whether the internal functional clock or the scan clock is transmitted to its corresponding clock domain. Next, at step 412, shift mode is entered and data is scanned or shifted into flip-flops of one or more scan chains by inputting data into the SI inputs of the flip-flops. The data may be provided by an automatic test equipment (ATE). Thereafter, at step 416, a capture mode is entered and one or more clock domains are tested by clocking data at the D inputs of one or more associated flip-flops. For example, a CDSTM may provide an appropriate clock signal to its corresponding clock domain such that a single clock pulse clocks data at the D inputs of one or more flip-flops of that clock domain. In such an instance, transition testing or “stuck-at fault testing” may be accomplished. In another example, a CDSTM may provide an appropriate clock signal to its corresponding clock domain such that two consecutive clock pulses are used to clock data at the D inputs of the one or more flip-flops of that clock domain. In such an instance, “transition fault delay testing” or “at speed scan testing” may be accomplished. The process continues at step 420, at which capture mode is terminated and shift mode is re-entered. The data clocked into the flip-flops during the capture mode is now shifted out of their respective one or more clock domains. This may be accomplished by shifting data out from the entire one or more scan chains in the integrated circuit chip. At step 424, the automatic test equipment (ATE) may analyze the data that has been shifted out of the one or more scan chains.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiments disclosed, but that the invention will include all embodiments falling within the scope of the appended claims.

What is claimed is:

1. A method of scan testing a digital integrated circuit chip comprising:
inputting a single scan clock for said scan testing by way of using a single pin of said digital integrated circuit chip;
first shifting data into one or more flip-flops of one or more scan chains by clocking said data into one or more scan in (SI) inputs of said one or more flip-flops using said single scan clock, said first shifting performed by first setting each of one or more scan enable (SE) or test enable (TE) inputs of said one or more flip-flops to a first value;
selectively clocking flip-flops of a clock domain of one or more clock domains using an output generated by a designated flip-flop of said one or more flip-flops of said one or more scan chains, said selectively clocking performed by setting said one or more SE or TE inputs of said one or more flip-flops of said one or more scan chains to a second value such that the data (D) inputs of said one or more flip-flops of said clock domain are clocked in; and
second shifting data from said one or more flip-flops of said one or more scan chains by clocking said data using said one or more scan in (SI) inputs of said one or more flip-flops using said single scan clock, said second shifting performed by second setting said one or more SE or TE inputs of said one or more flip-flops to said first value, said second shifting occurring after said selectively clocking is performed, said first shifting determining a state of said designated flip-flop prior to performing said selectively clocking.

2. The method of claim 1 wherein said selectively clocking comprises applying a single clock pulse.

3. The method of claim 2 wherein said single clock pulse is used to perform stuck-at fault testing of said clock domain.

4. The method of claim 1 wherein said selectively clocking comprises applying two consecutive clock pulses.

5. The method of claim 4 wherein said two consecutive clock pulses is used to perform transition fault delay testing.

6. The method of claim 1 wherein said first value comprises a binary value.

7. The method of claim 6 wherein said one or more SE or TE inputs are provided by a signal external to said digital integrated circuit chip.

8. The method of claim 7 wherein said signal is delivered to said digital integrated circuit chip by way of a single pin of said digital integrated circuit chip.

9. The method of claim 8 wherein said signal is provided by an automatic test equipment (ATE).

10. The method of claim 1 wherein an output (Q) of said designated flip-flop is transmitted to one or more flip-flops of said clock domain, by way of logic circuitry, said logic circuitry comprising a two input multiplexer, said two input multiplexer inputting said output and a functional clock of said clock domain.

11. The method of claim 10 wherein said logic circuitry further comprises an OR gate.

12. The method of claim 10 wherein said logic circuitry further comprises an AND gate.

13. The method of claim 1 wherein said selectively clocking controls the maximum power consumption of said digital integrated circuit chip.

14. The method of claim 1 wherein said selectively clocking minimizes cross clock domain violations of said digital integrated circuit chip.

15. A system for scan testing a digital integrated circuit chip comprising:
one or more clock domains; and
one or more clock domain scan test modules, each of said one or more clock domain scan test modules generating a clock domain clock signal for its corresponding clock domain of said one or more clock domains, said each of said one or more clock domain scan test modules comprising:
a flip-flop for generating an output, said output connected to a data (D) input of said flip-flop, said flip-flop controlled by a first control signal used to select said data (D) input or a scan in (SI) input of said flip-flop;
an OR gate for receiving said control flip-flop output and said first control signal, said OR gate generating an OR gate output;
an AND gate for receiving said OR gate output and a scan clock, said AND gate generating an AND gate output; and
a multiplexer for receiving said AND gate output and an internal functional clock of said digital integrated circuit chip, said multiplexer generating a multiplexer output that is transmitted to said corresponding clock domain, said first control signal determining if data is clocked into said SI input of said flip-flop and other flip-flops of one or more scan chains of said digital integrated circuit or if data is clocked into said D input of said flip-flop and other D inputs of flip-flops of said corresponding clock domain, said scan clock input into said digital integrated circuit using a first pin of said digital integrated circuit chip, said scan testing of said one or more clock domains performed using said scan clock.

16. The system of claim 15 wherein said first control signal is provided from an external source to said digital integrated circuit chip.

17. The system of claim 16 wherein said first control signal is delivered from said external source to said digital integrated circuit chip by way of a second pin of said digital integrated circuit chip.

18. The system of claim 15 wherein said first control signal comprises a binary value.

19. The system of claim 15 wherein one of two inputs of said multiplexer is selected by a second control signal.

20. The system of claim 15 wherein said first control signal comprises a scan enable (SE) or test enable (TE) input.

21. The system of claim 15 wherein an output (Q) of a flip-flop of said other flip-flops of said one or more scan chains is input into a scan input (SI) of the next consecutive flip-flop of said other flip-flops of said one or more scan chains.

22. The system of claim 15 wherein said first control signal and said scan clock are provided by an automatic test equipment (ATE).

23. A system for scan testing a digital integrated circuit chip comprising:
one or more clock domains; and
one or more clock domain scan test modules, said each of said one or more clock domain scan test modules clocking its corresponding clock domain of said one or more clock domains by way of utilizing a single scan clock that is input into said digital integrated circuit using a first pin of said digital integrated circuit chip.

24. The system of claim 23 wherein each of said one or more clock domain scan test modules comprises:
a flip-flop for generating an output, said output connected to a data (D) input of said flip-flop, said flip-flop controlled by a first control signal used to select said data (D) input or a scan in (SI) input of said flip-flop.

25. The system of claim 24 wherein each of said one or more clock domain scan test modules further comprises:
an OR gate for receiving said control flip-flop output and said first control signal, said OR gate generating an OR gate output.

26. The system of claim 25 wherein each of said one or more clock domain scan test modules further comprises:
an AND gate for receiving said OR gate output and a scan clock, said AND gate generating an AND gate output.

27. The system of claim 26 wherein each of said one or more clock domain scan test modules further comprises:
a multiplexer for receiving said AND gate output and an internal functional clock of said digital integrated circuit chip, said multiplexer generating a multiplexer output that is transmitted to said corresponding clock domain, said first control signal determining if data is clocked into said SI input of said flip-flop and other flip-flops of one or more scan chains of said digital integrated circuit or if data is clocked into said D input of said flip-flop and other D inputs of flip-flops of said corresponding clock domain, said scan clock input into said digital integrated circuit using a first pin of said digital integrated circuit chip, said scan testing of said one or more clock domains performed using said scan clock.

28. The system of claim 27 wherein said first control signal is provided from an external source to said digital integrated circuit chip.

29. The system of claim 28 wherein said first control signal is delivered from said external source to said digital integrated circuit chip by way of a second pin of said digital integrated circuit chip.

30. The system of claim 27 wherein said first control signal comprises a binary value.

31. The system of claim 27 wherein one of two inputs of said multiplexer is selected by a second control signal.

32. The system of claim 27 wherein said first control signal comprises a scan enable (SE) or test enable (TE) input.

33. The system of claim 27 wherein an output (Q) of a flip-flop of said other flip-flops of said one or more scan chains is input into a scan input (SI) of the next consecutive flip-flop of said other flip-flops of said one or more scan chains.

34. The system of claim 27 wherein said first control signal and said scan clock are provided by an automatic test equipment (ATE).
